(19) United States
(12) Patent Application Publication
(10) Pub. No.: US 2026/0150330 A1
(43) Pub. Date: May 28, 2026

(54) HIGH-BREAKDOWN VOLTAGE SEMICONDUCTOR DEVICES WITH SINGLE EVENT BURNOUT MITIGATION STRUCTURES AND METHODS OF MAKING THE SAME

(71) Applicant: Vorago Technologies, Inc., Austin, TX (US)

(72) Inventors: Patrice M. Parris, Phoenix, AZ (US); David R. Gifford, Pflugerville, TX (US)

(21) Appl. No.: 18/957,153

(22) Filed: Nov. 22, 2024

(51) Int. Cl. H01L 29/78; H01L 23/552; H01L 29/06

(52) U.S. Cl. CPC H10D 30/65; H10D 62/10; H10W 42/20

(57) ABSTRACT

Examples of high-breakdown voltage semiconductor devices with single event burnout mitigation structures and methods of making the same are described. The high-breakdown voltage semiconductor device includes a first single event burnout (SEB) structure formed with a first edge of the first SEB structure: (1) adjacent to a first edge of a well, or (2) arranged at a first distance from the first edge of the well. The high-breakdown voltage semiconductor device further includes a second SEB structure that is formed above the first SEB structure, with a second edge arranged at a second distance, equal to or greater than the first distance, from the first edge of the well. The combination of the first SEB structure and the second SEB structure offers a low resistance path to any current flow between the substrate and the body contact caused by single event burnout associated with the high-breakdown voltage semiconductor device.

### BACKGROUND

Semiconductor devices with a high drain to source breakdown voltage are often used for implementing high-voltage and power semiconductor devices. One example of such semiconductor devices is a laterally-diffused metal oxide semiconductor (LDMOS) device. In environments with ionizing radiation, after a particle strike, a large number of electron-hole pairs are generated along the strike path. In a normally-biased, NLDMOS, for example, the holes are pulled to the source side and the electrons are pulled to the drain side, thereby forming currents in a parasitic NPN bipolar transistor with the P-type region in the middle and the N-type source and N-type drain on the sides. The hole current flowing across the P-type region leads to a voltage drop across the P-type region, turning on the parasitic NPN bipolar transistor. The NPN bipolar transistor stays on because of the high voltage being applied to the drain of the LDMOS transistor. As a result, the parasitic NPN bipolar transistor becomes self-sustaining, and the increasing number of carriers causes avalanche multiplication in the high electric field region. This, in turn, causes single event burnout (SEB), causing the LDMOS device to fail.

Accordingly, there is a need for structures, and processes for making such structures, which help devices, such as LDMOS devices, be more robust with respect to single event burnout events, as well as hardening them against the effects of radiation.

### SUMMARY

In one example, the present disclosure relates to a high-breakdown voltage semiconductor device comprising a substrate of a first conductivity type. The high-breakdown voltage semiconductor device may further comprise a well of a second conductivity type, opposite of the first conductivity type, formed in the substrate. The high-breakdown voltage semiconductor device may further comprise a source and a drain, where the high-breakdown voltage semiconductor device is configured to withstand a high-breakdown voltage between the drain and the source, and a body contact.

The high-breakdown voltage semiconductor device may further comprise a first single event burnout (SEB) structure formed in a first region of the substrate, where a first edge of the first SEB structure: (1) is adjacent to a first edge of the well of the second conductivity type, or (2) is arranged at a first distance from the first edge of the well of the second conductivity type. The high-breakdown voltage semiconductor device may further comprise a second SEB structure formed in a second region of the substrate, above the first SEB structure, where a second edge of the second SEB structure is arranged at a second distance, equal to or greater than the first distance, from the first edge of the well of the second conductivity type, and where a combination of the first SEB structure and the second SEB structure is configured to offer a low resistance path to any current flow between the substrate and the body contact caused by an ionizing strike associated with the high-breakdown voltage semiconductor device.

In another aspect, the present disclosure relates to a high-breakdown voltage semiconductor device comprising a substrate of a first conductivity type. The high-breakdown voltage semiconductor device may further comprise a well of a second conductivity type, opposite of the first conductivity type, formed in the substrate. The high-breakdown voltage semiconductor device may further comprise a source and a drain, where the high-breakdown voltage semiconductor device is configured to withstand a high-breakdown voltage between the drain and the source, and a body contact.

The high-breakdown voltage semiconductor device may further comprise a first single event burnout (SEB) structure formed in a first region of the substrate, where a first edge of the first SEB structure: (1) is adjacent to a first edge of the well of the second conductivity type, or (2) is arranged at a first distance from the first edge of the well of the second conductivity type. The high-breakdown voltage semiconductor device may further comprise a second SEB structure formed in a second region of the substrate, above the first SEB structure, where a second edge of the second SEB structure is arranged at a second distance, equal to or greater than the first distance, from the first edge of the well of the second conductivity type.

The high-breakdown voltage semiconductor device may further comprise a third SEB structure formed in a third region of the substrate, above the second SEB structure, where a third edge of the third SEB structure is arranged at a third distance, equal to or greater than the second distance, from the first edge of the well of the second conductivity type. The combination of the first SEB structure, the second SEB structure, and the third SEB structure is configured to offer a low resistance path to any current flow between the substrate and the body contact caused by an ionizing strike associated with the high-breakdown voltage semiconductor device.

In yet another aspect, the present disclosure relates to a high-breakdown voltage semiconductor device comprising a substrate and a first well formed in the substrate. The high-breakdown voltage semiconductor device may further comprise a first region formed in the first well, where the first region is configurable as a first source or a first drain. The high-breakdown voltage semiconductor device may further comprise a second well formed in the substrate. The high-breakdown voltage semiconductor device may further comprise a second region formed in the second well, where the second region is configurable as a second source or a second drain, allowing the high-breakdown voltage semiconductor device to operate as a bidirectional device.

The high-breakdown voltage semiconductor device may further comprise a first single event burnout (SEB) structure formed in a first region of the substrate, where a first edge of the first SEB structure: (1) is adjacent to a first edge of the first well, or (2) is arranged at a first distance from the first edge of the first well, and where a second edge of the first SEB structure: (1) is adjacent to a second edge of the second well, or (2) is arranged at second distance, equal to the first distance, from the second edge of the second well. The high-breakdown voltage semiconductor device may further comprise a second SEB structure formed in a second region of the substrate, above the first SEB structure, where a third edge of the second SEB structure is arranged at a third distance, equal to or greater than the first distance, from the first edge of the first well, and where a fourth edge of the second SEB structure is arranged at a fourth distance, equal to the third distance, from the second edge of the second well. The combination of the first SEB structure and the second SEB structure is configured to offer a low resistance path to any current flow between the substrate and the first body contact or between the substrate and the second body contact caused by an ionizing strike associated with the high-breakdown voltage semiconductor device.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a cross-section view of several single event burnout (SEB) mitigation structures formed in a unidirectional non-isolated laterally-diffused metal oxide semiconductor (NLDMOS) device in accordance with one example;

FIG. 2 shows a cross-section view of several single event burnout (SEB) mitigation structures formed in a unidirectional NLDMOS device in accordance with another example;

FIG. 3 shows a cross-section view of several single event burnout (SEB) mitigation structures formed in a unidirectional NLDMOS device in accordance with another example;

FIG. 4 shows a cross-section view of several single event burnout (SEB) mitigation structures formed in a unidirectional NLDMOS device in accordance with another example;

FIG. 5 shows a cross-section view of several single event burnout (SEB) mitigation structures formed in a bidirectional NLDMOS device in accordance with one example;

FIG. 6 shows a cross-section view of several single event burnout (SEB) mitigation structures formed in a bidirectional NLDMOS device in accordance with another example; and

FIG. 7 shows a diagram of an external single event burnout (SEB)-resistant series transistor for an NLDMOS device in accordance with an example.

### DETAILED DESCRIPTION

Examples described in this disclosure relate to high-breakdown voltage semiconductor devices with single event burnout (SEB) mitigation structures and methods of making the same. As used herein the term “high-breakdown voltage” includes a range of voltages between 3 volts to 5000 volts. The high-breakdown voltage may refer to the drain to source voltage of a semiconductor device, such as a laterally-diffused metal oxide semiconductor (LDMOS) device. Such LDMOS devices may be included as part of various types of integrated circuits. Integrated circuits include but are not limited to Field-Programmable Gate Arrays (FPGAs), Application-Specific Integrated Circuits (ASICs), Application-Specific Standard Products (ASSPs), System-on-a-Chip systems (SoCs), Complex Programmable Logic Devices (CPLDs), Digital-Signal Processors (DSPs), Power Management Integrated Circuits (PMICs), controllers (e.g., automotive controllers, communication controllers, IoT controllers), sensors, image sensors, or other types of integrated circuits.

In environments with ionizing radiation, after a particle strike, a large number of electron-hole pairs are generated along the strike path. In a normally-biased, NLDMOS, for example, the holes are pulled to the source side and the electrons are pulled to the drain side, thereby forming currents in a parasitic NPN bipolar transistor with the P-type region in the middle and the N-type source and N-type drain on the side. The hole current flowing across the P-type region leads to a voltage drop across the P-type region, turning on the parasitic NPN bipolar transistor. The NPN bipolar transistor stays on because of the high voltage being applied to the drain of the LDMOS transistor. As a result, the parasitic NPN bipolar transistor becomes self-sustaining, and the increasing number of carriers causes avalanche multiplication in the high electric field region. This, in turn, causes single event burnout causing the LDMOS device to fail. Examples described in this disclosure relate to radiation-hardened high-breakdown voltage semiconductor devices with single event burnout (SEB) mitigation structures and methods of making the same.

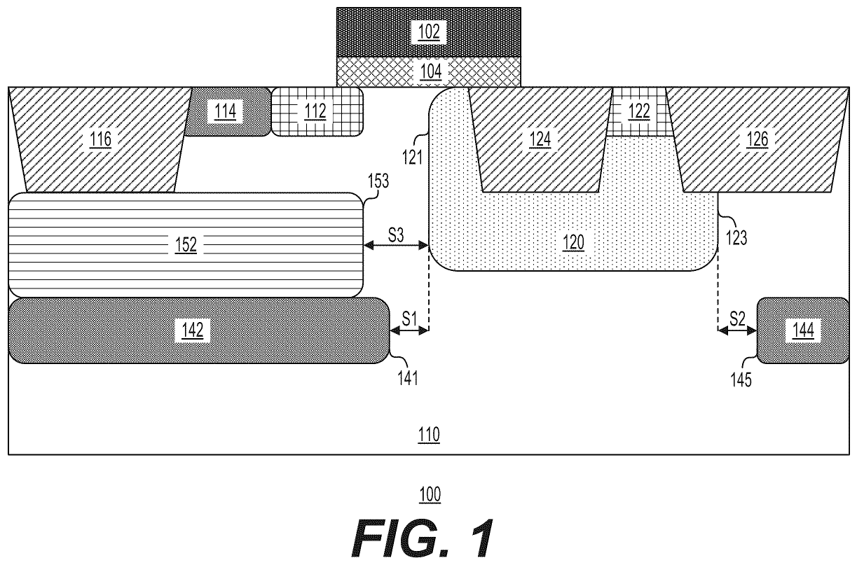

FIG. 1 shows a cross-section view of several single event burnout (SEB) mitigation structures formed in a unidirectional non-isolated laterally-diffused metal oxide semiconductor (NLDMOS) device 100 in accordance with one example. To illustrate the structure and the functionality of the SEB mitigation structures, certain portions of unidirectional NLDMOS device 100 are emphasized. A complete unidirectional NLDMOS device may include contacts and other structures for operation that are not shown in FIG. 1. The use of the SEB mitigation structures formed in unidirectional NLDMOS device 100, however, is not limited to a particular implementation of the unidirectional NLDMOS. In addition, the SEB mitigation structures described herein can be used with other high-voltage device designs, including isolated LDMOS devices, Insulated Gate Bipolar Transistors (IGBTs), vertical double-diffused metal-oxide semiconductor (VDMOS) devices or trench metal-oxide semiconductor (TMOS) devices.

Unidirectional NLDMOS device 100 includes a gate electrode 102 and a gate insulator layer 104. Unidirectional NLDMOS device 100 includes a P-type substrate 110. Unidirectional NLDMOS device 100 is non-isolated because the channel is in contact with the substrate. An N-type region 120 is formed in a P-type substrate 110. N-type region 120 may be formed by implanting n-type dopants, such as phosphorous, arsenic, antimony, bismuth, or lithium into the P-type substrate 110. Unidirectional NLDMOS device 100 further includes a source (N+-type in this example) 112 and a P+ body contact 114. As an example, the P+ body contact 114 may have a doping concentration of 1×10²⁰ atoms per cm³ and the P-type substrate may have a doping concentration of 1×10¹⁶ atoms per cm³. The atoms may correspond to boron or another P-type implant material. Unidirectional NLDMOS device 100 is further shown with an isolation region 116. Unidirectional NLDMOS device 100 further includes a drain (N+-type in this example) 122. Drain 122 is formed within N-type region 120. Unidirectional NLDMOS device 100 further includes isolation regions 124 and 126. Isolation regions 116, 124, and 126 may be formed by depositing insulating material and selectively removing portions of the insulating material. Insulating materials such as silicon dioxide, silicon nitride, or other similar insulation materials may be used. In one example, the isolation regions may be configured as shallow trench isolation (STI) structures. Instead of STIs, local oxidation of silicon (LOCOS) may also be used.

As noted earlier, in environments with ionizing radiation, after an energetic strike, a large number of electron-hole pairs are generated along the strike path. The holes are pulled to the source side (e.g., towards the region associated with source 112) and the electrons are pulled to the drain side (e.g., towards the regions associated with n-type region 120 and drain 122), thereby forming currents in a parasitic NPN bipolar transistor within the P-type region in the middle and the N+-type source and N-type region and drain on the side. The hole current flowing across the P-type region leads to a voltage drop across the P-type region, turning on the parasitic NPN bipolar transistor. The NPN bipolar transistor stays on because of the high voltage being applied to the drain (e.g., drain 122) of the LDMOS transistor. As a result, the parasitic NPN bipolar transistor becomes self-sustaining, and the increasing number of carriers causes avalanche multiplication in the high electric field region. This, in turn, causes single event burnout causing the LDMOS device without the SEB mitigation structures to fail.

With continued reference to FIG. 1, to mitigate the SEB, during the formation of unidirectional NLDMOS device 100, one or both of SEB mitigation structures 142 and 144 may be formed. SEB mitigation structures 142 and 144 may be formed by implanting P-type dopants into the P-type substrate 110. Using masks, P-type dopants are implanted in a manner that SEB mitigation structure 142 is formed with an edge 141 that is spaced from an edge 121 of N-type region 120 by a distance of S1. The distance S1 may have a value of zero, such that the edge 141 of SEB mitigation structure 142 is adjacent to edge 121 of N-type region 120. As used herein, the use of the term “adjacent” includes the arrangement where SEB mitigation structure 142 is formed in a region below N-type region 120 (e.g., as shown in FIG. 1). SEB mitigation structure 142 decreases the resistance to the current that is flowing as a result of the energetic strike between substrate 110 and P+ body contact 114. In other words, in the absence of SEB mitigation structure 142, there will be a higher resistance path for any current flowing from substrate 110 to the P+ body contact 114.

In addition, SEB mitigation structure 144 is formed with an edge 145 that is spaced from an edge 123 of N-type region 120 by a distance of S2, which may be the same as S1. The distance S2 may have a value of zero, such that the edge 145 of SEB mitigation structure 144 is adjacent to edge 123 of N-type region 120. As used herein, the use of the term “adjacent” includes the arrangement where SEB mitigation structure 144 is formed in a region below N-type region 120 (e.g., as shown in FIG. 1). In this manner, each of SEB mitigation structures 142 and 144 may be spaced away from N-type region 120 by the same distance. SEB mitigation structure 144 also lowers the resistance to the current flowing through unidirectional NLDMOS device 100.

Still referring to FIG. 1, to further mitigate SEB, during the formation of unidirectional NLDMOS device 100, SEB mitigation structure 152 is optionally formed. SEB mitigation structure 152 may be formed by implanting P-type dopants into the P-type substrate 110. Using masks, P-type dopants are implanted in a manner that SEB mitigation structure 152 is formed with an edge 153 that is spaced from edge 121 of N-type region 120 by a distance of S3. The distance S3 is often greater than the distance S1 described earlier with respect to SEB mitigation structure 142 and the distance S2 described earlier with respect to SEB mitigation structure 144. In other words, SEB mitigation structure 152 is spaced further away from N-type region 120 relative to SEB mitigation structures 142 and 144. SEB mitigation structure 152 also helps decrease the resistance to the current that is flowing as a result of the particle strike between substrate 110 and P+ body contact 114. In other words, in the absence of SEB mitigation structure 152, there will be a higher resistance path for any current flowing from substrate 110 to the P+ body contact 114.

With continued reference to FIG. 1, to further mitigate SEB, during the formation of unidirectional NLDMOS device 100, various methods, like silicidation, can be employed to minimize the resistance between P+ body contact 114 and source 112. This opposes the forward biasing of the junction between source 112 and substrate 110, and thereby mitigates the initiation of the SEB event.

SEB mitigation structures 142, 144, and 152 can be formed regardless of whether unidirectional NLDMOS device 100 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 1 shows a specific configuration of SEB mitigation structures 142, 144, and 152 in terms of their location and shape, the SEB mitigation structures may be formed in additional, or alternative, locations and may have different shapes than shown in FIG. 1. As an example, SEB mitigation structures 142 and 144 could be formed as a single blanket layer formed at a depth beneath N-type regions like N-type region 120. The use of the blanket layer as one, or a part, of the SEB mitigation structures may allow one to remove additional processing steps associated with the formation of separate SEB mitigation structures 142 and 144.

In another example, the integrated circuit having such NLDMOS devices may also include complimentary metal-oxide semiconductor (CMOS) devices, which may be formed in different areas of the chip. In such an example, SEB mitigation structure 152 along with one or both of SEB mitigation structures 142 and 144 may be the layers that are formed in the areas corresponding to the CMOS devices. Alternatively, SEB mitigation structure 152 along with a single blanket layer replacing the SEB mitigation structures 142 and 144 may be the layers that are formed in the areas corresponding to the CMOS devices. One function of the such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

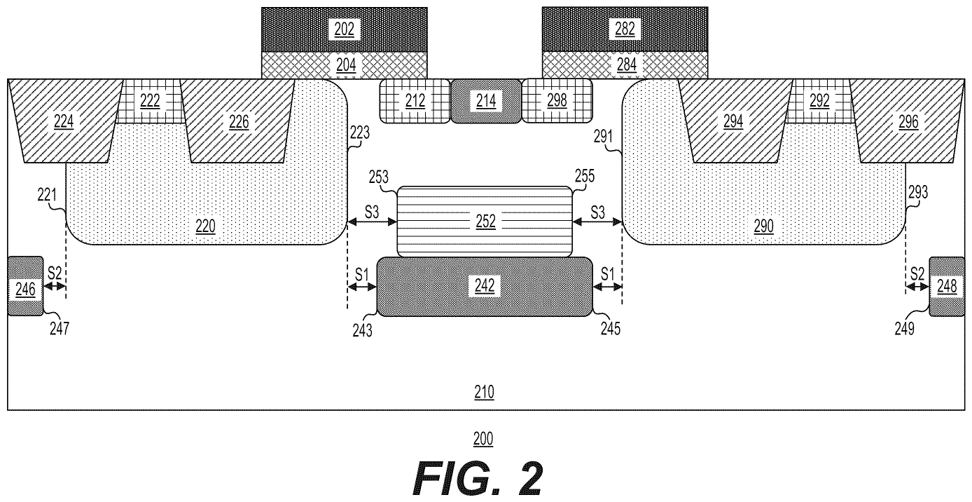

FIG. 2 shows a cross-section view of several single event burnout (SEB) mitigation structures formed in a unidirectional NLDMOS device 200 in accordance with another example. Unidirectional NLDMOS device 200 is different from unidirectional NLDMOS device 100 of FIG. 1 in that unidirectional NLDMOS device 200 has a shared body contact. To illustrate the structure and the functionality of the SEB mitigation structures, certain portions of unidirectional NLDMOS device 200 are emphasized. A complete unidirectional NLDMOS device may include contacts and other structures for operation that are not shown in FIG. 2. The use of the SEB mitigation structures formed in unidirectional NLDMOS device 200, however, is not limited to a particular implementation of the unidirectional NLDMOS. In addition, the SEB mitigation structures described herein can be used with other high-voltage device designs, including isolated LDMOS devices, Insulated Gate Bipolar Transistors (IGBTs), vertical double-diffused metal-oxide semiconductor (VDMOS) devices or trench metal-oxide semiconductor (TMOS) devices.

In this example, unidirectional NLDMOS device 200 includes two LDMOS transistors that share a body contact. Unidirectional NLDMOS device 200 includes a P-type substrate 210. Unidirectional NLDMOS device 200 includes a gate electrode 202 and a gate insulator layer 204. Unidirectional NLDMOS device 200 further includes another gate electrode 282 and a gate insulator layer 284. Unidirectional NLDMOS device 200 is non-isolated because the channel is in contact with the substrate. A first N-type region 220 is formed in the P-type substrate 210. A second N-type region 290 is formed in the P-type substrate 210, as well. Each of the N-type regions 220 and 290 may be formed by implanting N-type dopants, such as phosphorous, arsenic, antimony, bismuth, or lithium into the P-type substrate 210. Unidirectional NLDMOS device 200 further includes a first source (N+-type in this example) 212, a second source (N+-type in this example) 298, and a shared P+ body contact 214. As an example, the P+ body contact 214 may have a doping concentration of 1×10²⁰ atoms per cm³ and the P-type substrate may have a doping concentration of 1×10¹⁶ atoms per cm³. The atoms may correspond to boron or another P-type implant material.

Unidirectional NLDMOS device 200 is further shown with isolation regions 224, 226, 294, and 296. Isolation regions 224, 226, 294, and 296 may be formed by depositing insulating material and selectively removing portions of the insulating material. Insulating materials such as silicon dioxide, silicon nitride, or other similar insulation materials may be used. In one example, the isolation regions may be configured as shallow trench isolation (STI) structures. Instead of STIs, local oxidation of silicon (LOCOS) may also be used. Unidirectional NLDMOS device 200 further includes a drain (N+-type in this example) 222 and another drain (N+-type in this example) 292. Drain 222 is formed within N-type region 220 and drain 292 is formed within N-type region 290.

As noted earlier, in environments with ionizing radiation, after a particle strike, a large number of electron-hole pairs are generated along the strike path. The holes are pulled to the source side (e.g., towards the region associated with source 212 or source 298) and the electrons are pulled to the drain side (e.g., towards the region associated with drain 222 or drain 292), thereby forming a parasitic NPN bipolar transistor within the P-type region in the middle and the N+-type source and N+-type drain on the side. The hole current flowing across the P-type region leads to a voltage drop across the P-type region, turning on the parasitic NPN bipolar transistor. The NPN bipolar transistor stays on because of the high voltage being applied to the drain (e.g., drain 222 or drain 292) of the LDMOS transistor. As a result, the parasitic NPN bipolar transistor becomes self-sustaining, and the increasing number of carriers causes avalanche multiplication in the high electric field region. This, in turn, causes single event burnout causing the LDMOS device without the SEB mitigation structures to fail.

With continued reference to FIG. 2, to mitigate the SEB, during the formation of unidirectional NLDMOS device 200, some or all of SEB mitigation structures 242, 246, and 248 may be formed. SEB mitigation structures 242, 246, and 248 may be formed by implanting P-type dopants into the P-type substrate 210. Using masks, P-type dopants are implanted in a manner that SEB mitigation structure 242 is formed with an edge 243 that is spaced from an edge 223 of N-type region 220 by a distance of S1 and with another edge 245 that is spaced from an edge 291 of N-type region 290 by the distance of S1. The distance S1 may have a value of zero, such that the edge 243 of SEB mitigation structure 242 is adjacent to edge 223 of N-type region 220. As used herein, the use of the term “adjacent” includes the arrangement where SEB mitigation structure 242 is formed in a region below N-type region 220 (e.g., as shown in FIG. 2). Similarly, the edge 245 of SEB mitigation structure can be adjacent to edge 291 of N-type region 290 even though SEB mitigation structure 242 is formed in a region below N-type region 290.

SEB mitigation structure 242 decreases the resistance to the current that is flowing as a result of the energetic strike between substrate 210 and P+ body contact 214. In other words, in the absence of SEB mitigation structure 242, there will be a higher resistance path for any current flowing from substrate 210 to the P+ body contact 214. In addition, SEB mitigation structure 246 is formed with an edge 247 that is spaced from an edge 221 of N-type region 220 by a distance of S2. Moreover, SEB mitigation structure 248 is formed with an edge 249 that is spaced from an edge 293 of N-type region 290 by a distance of S2. The distance S2 may have a value of zero, such that the edge 247 of SEB mitigation structure 246 is adjacent to edge 221 of N-type region 220. As used herein, the use of the term “adjacent” includes the arrangement where SEB mitigation structure 246 is formed in a region below N-type region 220 (e.g., as shown in FIG. 2). Similarly, the edge 249 of SEB mitigation structure 248 can be adjacent to edge 293 of N-type region 290 even though SEB mitigation structure 248 is formed in a region below N-type region 290. In this manner, each of SEB mitigation structures 246 and 248 is spaced away from a respective N-type region (e.g., N-type region 220 or N-type region 290) by the same distance S2. Each of SEB mitigation structures 246 and 248 also lower the resistance to the current flowing through unidirectional NLDMOS device 200 to body contact 214.

Still referring to FIG. 2, to further mitigate SEB, during the formation of unidirectional NLDMOS device 200, SEB mitigation structure 252 may be formed. SEB mitigation structure 252 may be formed by implanting P-type dopants into the P-type substrate 210. Using masks, P-type dopants are implanted in a manner that SEB mitigation structure 252 is formed with an edge 253 that is spaced from edge 223 of N-type region 220 by a distance of S3 and spaced from edge 291 of N-type region 290 by a distance of S3. The distance S3 is usually greater than the distance S1 described earlier with respect to SEB mitigation structure 242. In other words, SEB mitigation structure 252 is spaced further away from N-type region 220 relative to SEB mitigation structure 242. Similarly, SEB mitigation structure 252 is spaced further away from N-type region 290 relative to SEB mitigation structure 242. SEB mitigation structure 252 also helps decrease the resistance to the current that is flowing as a result of the energetic strike between substrate 210 and P+ body contact 214. In other words, in the absence of SEB mitigation structure 252, there will be a higher resistance path for any current flowing from substrate 210 to the P+ body contact 214.

With continued reference to FIG. 2, to further mitigate SEB, during the formation of unidirectional NLDMOS device 200, various methods, like silicidation, can be employed to minimize the resistance between P+ body contact 214 and source 212 and source 298. This opposes the forward biasing of the junction between source 212 and substrate 210 or of the junction between source 298 and substrate 210, and thereby mitigates the initiation of the SEB event.

SEB mitigation structures 242, 246, 248, and 252 can be formed regardless of whether unidirectional NLDMOS device 200 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 2 shows a specific configuration of SEB mitigation structures 242, 246, 248, and 252 in terms of their location and shape, the SEB mitigation structures may be formed in additional, or alternative, locations and may have different shapes than shown in FIG. 2. As an example, SEB mitigation structures 242, 246, and 248 could be formed as a single blanket layer formed at a depth beneath N-type regions like N-type region 220. The use of the blanket layer as one, or a part, of the SEB mitigation structures may allow one to remove additional processing steps associated with the formation of separate SEB mitigation structures 242, 246 and 248.

In another example, the integrated circuit having NLDMOS devices may also include complimentary metal-oxide semiconductor (CMOS) devices, which may be formed in different areas of the chip. In such an example, SEB mitigation structure 252 along with one or more of SEB mitigation structures 242, 246, and 248 may be the layers that are formed in the areas corresponding to the CMOS devices. Alternatively, SEB mitigation structure 252 along with a single blanket layer replacing the SEB mitigation structures 242, 246, and 248 may be the layers that are formed in the areas corresponding to the CMOS devices. One function of such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

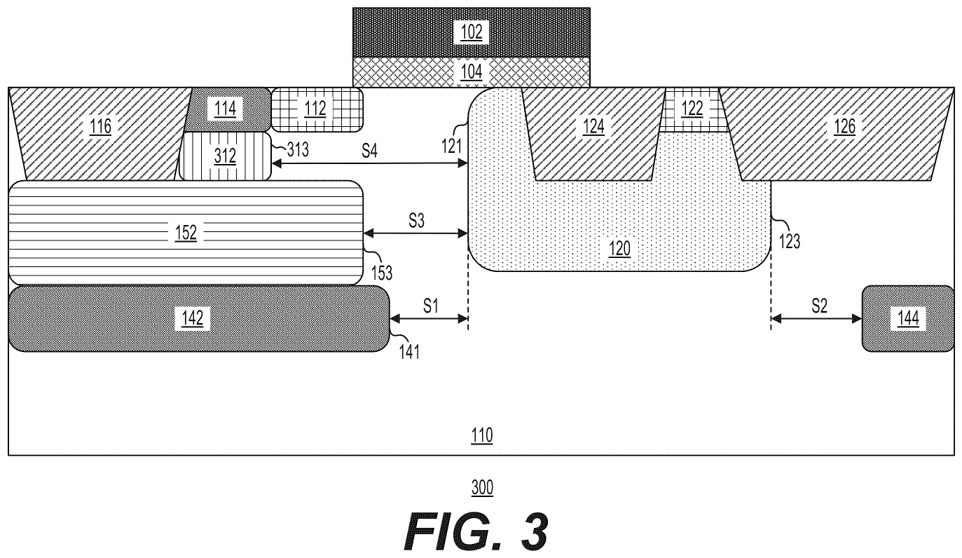

FIG. 3 shows a cross-section view of several single event burnout (SEB) mitigation structures formed in a unidirectional NLDMOS device 300 in accordance with one example. To illustrate the structure and the functionality of the SEB mitigation structures, certain portions of unidirectional NLDMOS device 300 are emphasized. A complete unidirectional NLDMOS device may include contacts and other structures for operation that are not shown in FIG. 3. The use of the SEB mitigation structures formed in unidirectional NLDMOS device 300, however, is not limited to a particular implementation of the unidirectional NLDMOS. In addition, the SEB mitigation structures described herein can be used with other high-voltage device designs, including Insulated Gate Bipolar Transistors (IGBTs), vertical double-diffused metal-oxide semiconductor (VDMOS) devices or trench metal-oxide semiconductor (TMOS) devices.

The same or similar regions or structures that are shown in FIG. 3 are referred to using the same reference numbers as used in FIG. 1. As an example, unidirectional NLDMOS device 300 includes the SEB mitigation structures 142 and 152 described earlier with respect to FIG. 1. In addition, unidirectional NLDMOS device 300 includes another SEB mitigation structure 312. Using masks, P-type dopants are implanted in a manner that SEB mitigation structure 312 is formed with an edge 313 that is spaced from edge 121 of N-type region 120 by a distance of S4. The distance S4 is usually greater than the distance S3 described earlier with respect to SEB mitigation structure 152. In addition, the distance S4 is greater than the distances S1 and S2 described earlier with respect to SEB mitigation structures 142 and 144, respectively. In other words, SEB mitigation structure 312 is spaced further away from N-type region 120 relative to SEB mitigation structures 142, 144, and 152. SEB mitigation structure 312 also helps decrease the resistance to the current that is flowing as a result of the energetic strike between substrate 110 and P+body contact 114 by acting as a low resistance link between SEB mitigation structure 152 and P+body contact 114.

Depending on the process platform, SEB mitigation structure 312 may be made with one implant or a chain of multiple implants of different energies. Two such examples are a P-type SEB mitigation structure 312 formed by a single boron implant with dose between 1×10¹² and 1×10¹⁵ and energy between 25 keV and 600 keV or the SEB mitigation structure 312 formed by a chain of two boron implants, one with dose between 1×10¹² and 1×10¹⁵ and energy between 25 keV and 150 keV and a second with dose between 1×10¹² and 1×10¹⁵ and energy between 150 keV and 600 keV. In the absence of SEB mitigation structure 312, there will be a higher resistance path for any current flowing from substrate 110 to the P+ body contact 114.

Still referring to FIG. 3, to further mitigate SEB, during the formation of unidirectional NLDMOS device 300, various methods, like silicidation, can be employed to minimize the resistance between P+ body contact 114 and source 112. This opposes the forward biasing of the junction between source 112 and substrate 210, and thereby mitigates the initiation of the SEB event.

With continued reference to FIG. 3, SEB mitigation structures 142, 144, 152, and 312 can be formed regardless of whether unidirectional NLDMOS device 300 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 3 shows a specific configuration of SEB mitigation structures 142, 144, 152, and 312 in terms of their location and shape, the SEB mitigation structures may be formed in additional, or alternative, locations and may have different shapes than shown in FIG. 3. As an example, SEB mitigation structures 142 and 144 could be formed as a single blanket layer formed at a depth beneath N-type regions like 120. The use of the blanket layer as one, or a part, of the SEB mitigation structures may allow one to remove additional processing steps associated with the formation of separate SEB mitigation structures 142 and 144.

In another example, the integrated circuit having NLDMOS devices may also include complimentary metal-oxide semiconductor (CMOS) devices, which may be formed in different areas of the chip. In such an example, SEB mitigation structures 312 and 152 along with one or both of SEB mitigation structures 142 and 144 may be the layers that are formed in the areas corresponding to the CMOS devices. Alternatively, SEB mitigation structures 312 and 152 along with a single blanket layer replacing the SEB mitigation structures 142 and 144 may be the layers that are formed in the areas corresponding to the CMOS devices. One function of such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

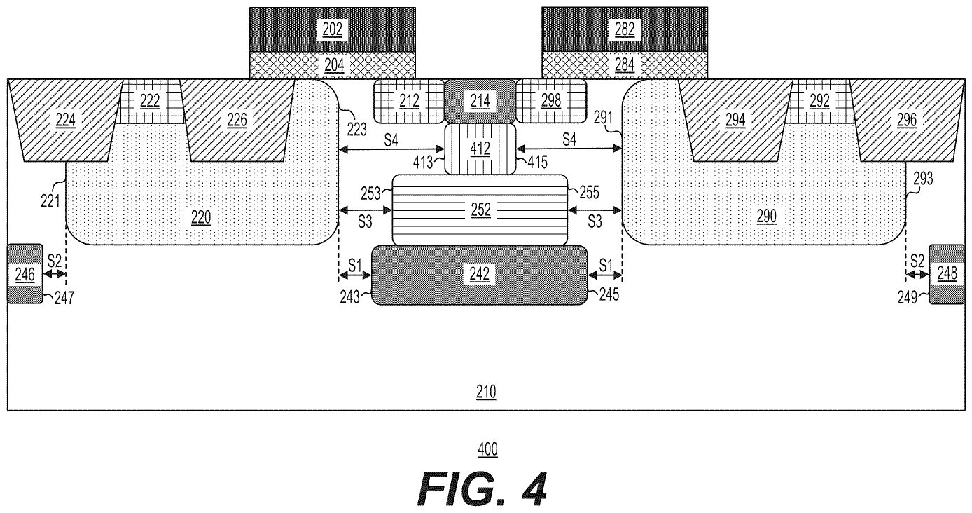

FIG. 4 shows a cross-section view of several single event burnout (SEB) mitigation structures formed in a unidirectional NLDMOS device 400 in accordance with another example. To illustrate the structure and the functionality of the SEB mitigation structures, certain portions of unidirectional NLDMOS device 400 are emphasized. A complete unidirectional NLDMOS device may include contacts and other structures for operation that are not shown in FIG. 4. The use of the SEB mitigation structures formed in unidirectional NLDMOS device 400, however, is not limited to a particular implementation of the unidirectional NLDMOS. In addition, the SEB mitigation structures described herein can be used with other high-voltage device designs, including isolated LDMOS devices, Insulated Gate Bipolar transistors (IGBTs), vertical double-diffused metal-oxide semiconductor (VDMOS) devices or trench metal-oxide semiconductor (TMOS) devices.

The same or similar regions or structures that are shown in FIG. 4 are referred to using the same reference numbers as used in FIG. 2. As an example, unidirectional NLDMOS device 400 includes the SEB mitigation structures 242, 246, 248, and 252 described earlier with respect to FIG. 2. In addition, unidirectional NLDMOS device 400 includes another SEB mitigation structure 412. Using masks, P-type dopants are implanted in a manner that SEB mitigation structure 412 is formed with an edge 413 that is spaced from edge 223 of N-type region 220 by a distance of S4 and another edge 415 that is spaced from edge 291 of N-type region 290 by the same distance of S4. The distance S4 is usually greater than the distance S3 described earlier with respect to SEB mitigation structure 252. In addition, the distance S4 is usually greater than the distance S1 described earlier with respect to SEB mitigation structure 242. In other words, SEB mitigation structure 412 is spaced further away from N-type region 220 and N-type region 290 relative to SEB mitigation structures 242 and 252. SEB mitigation structure 412 also helps decrease the resistance to the current that is flowing as a result of the particle strike between substrate 210 and the shared P+ body contact 214 by acting as a low resistance link between SEB mitigation structure 252 and P+body contact 214.

Depending on the process platform, SEB mitigation structure 412 may be made with one implant or a chain of multiple implants of different energies. Two such examples are a P-type SEB mitigation structure 412 formed by a single boron implant with dose between 1×10¹² and 1×10¹⁵ and energy between 25 keV and 600 keV or the SEB mitigation structure 412 formed by a chain of two boron implants, one with dose between 1×10¹² and 1×10¹⁵ and energy between 25 keV and 150 keV and a second with dose between 1×10¹² and 1×10¹⁵ and energy between 150 keV and 600 keV. In the absence of SEB mitigation structure 412, there will be a higher resistance path for any current flowing from substrate 210 to the P+ body contact 214.

Still referring to FIG. 4, to further mitigate SEB, during the formation of unidirectional NLDMOS device 400, various methods, like silicidation, can be employed to minimize the resistance between P+ body contact 214 and source regions 212 and 298. This opposes the forward biasing of the junction between source 212 and substrate 210 and of the junction between source 298 and substrate 210, and thereby mitigates the initiation of the SEB event.

With continued reference to FIG. 4, SEB mitigation structures 242, 246, 248, 252, and 412 can be formed regardless of whether unidirectional NLDMOS device 400 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 4 shows a specific configuration of SEB mitigation structures 242, 246, 248, 252, and 412 in terms of their location and shape, the SEB mitigation structures may be formed in additional, or alternative, locations and may have different shapes than shown in FIG. 4. As an example, SEB mitigation structures 242, 246, and 248 could be formed as a single blanket layer formed at a depth beneath N-type regions like 220. The use of the blanket layer as one, or a part, of the SEB mitigation structures may allow one to remove additional processing steps associated with the formation of separate SEB mitigation structures 242, 246 and 248.

In another example, the integrated circuit having NLDMOS devices may also include complimentary metal-oxide semiconductor (CMOS) devices, which may be formed in different areas of the chip. In such an example, SEB mitigation structures 412 and 252 along with one or more of SEB mitigation structures 242, 246, and 248 may be the layers that are formed in the areas corresponding to the CMOS devices. Alternatively, SEB mitigation structures 412 and 252 along with a single blanket layer replacing SEB mitigation structures 242, 246, and 248 may be the layers that are formed in the areas corresponding to the CMOS devices. One function of such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

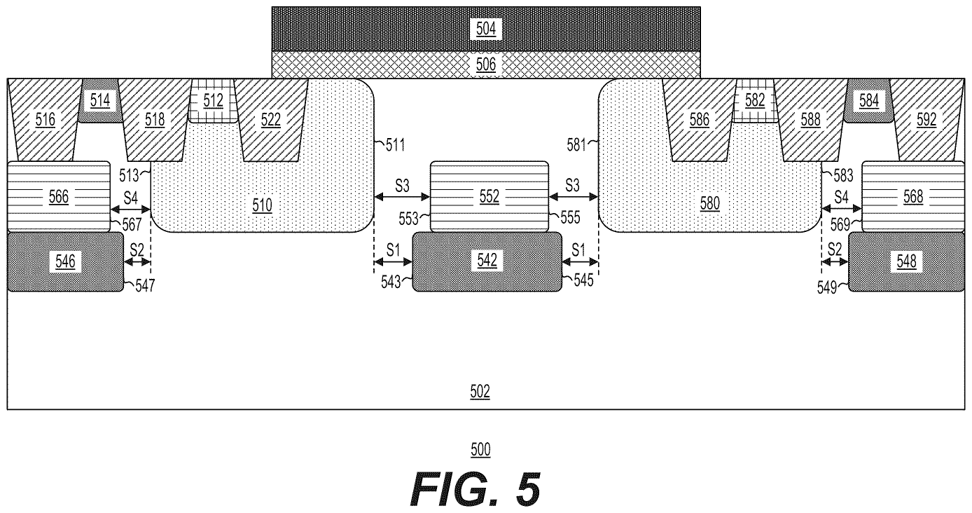

FIG. 5 shows a cross-section view of several single event burnout (SEB) mitigation structures formed in a bidirectional NLDMOS device 500 in accordance with one example. To illustrate the structure and the functionality of the SEB mitigation structures, certain portions of bidirectional NLDMOS device 500 are emphasized. A complete bidirectional NLDMOS device may include contacts and other structures for operation that are not shown in FIG. 5. The use of the SEB mitigation structures formed in bidirectional NLDMOS device 500, however, is not limited to a particular implementation of the bidirectional NLDMOS. In addition, the SEB mitigation structures described herein can be used with other high-voltage device designs, including Insulated Gate Bipolar Transistors (IGBTs), vertical double-diffused metal-oxide semiconductor (VDMOS) devices or trench metal-oxide semiconductor (TMOS) devices.

In this example, bidirectional NLDMOS device 500 can operate bidirectionally based on which of the source/drain regions is configured as a source or a drain. Bidirectional NLDMOS device 500 includes a P-type substrate 502. Bidirectional NLDMOS device 500 includes a gate electrode 504 and a gate insulator layer 506. Bidirectional NLDMOS device 500 is non-isolated because the channel is in contact with the substrate 502. A first N-type region 510 is formed in the P-type substrate 502. A second N-type region 580 is formed in the P-type substrate 502, as well. Each of the N-type regions 510 and 580 may be formed by implanting N-type dopants, such as phosphorous, arsenic, antimony, bismuth, or lithium into the P-type substrate 502. Bidirectional NLDMOS device 500 further includes a first source/drain (N+-type in this example) 512, a second source/drain (N+-type in this example) 582, a first P+ body contact 514, and a second P+ body contact 584. As an example, the P+ type body contact 514 and the P+ body contact 584 may have a doping concentration of 1×10²⁰ atoms per cm³ and the P-type substrate may have a doping concentration of 1×10¹⁶ atoms per cm³. The atoms may correspond to boron or another P-type implant material.

Bidirectional NLDMOS device 500 is further shown with isolation regions 516, 518, 522, 586, 588, and 592. Isolation regions 516, 518, 522, 586, 588, and 592 may be formed by depositing insulating material and selectively removing portions of the insulating material. Insulating materials such as silicon dioxide, silicon nitride, or other similar insulation materials may be used. In one example, the isolation regions may be configured as shallow trench isolation (STI) structures. Instead of STIs, local oxidation of silicon (LOCOS) may also be used.

As noted earlier, in environments with ionizing radiation, after an energetic strike, a large number of electron-hole pairs are generated along the strike path. The holes are pulled to the source side (e.g., towards N-type region 510 or 580 associated with source/drain 512 (when acting as the source) or source/drain 582 (when acting as the source)) and the electrons are pulled to the drain side (e.g., towards region 510 or 580 associated with source/drain 512 (when acting as the drain) or source/drain 582 (when acting as the drain)), thereby forming a parasitic NPN bipolar transistor within the P-type region in the middle and the N+-type source and N+-type drain on the side. The hole current flowing across the P-type region leads to a voltage drop across the P-type region, turning on the parasitic NPN bipolar transistor. The NPN bipolar transistor stays on because of the high voltage being applied to the drain (e.g., source/drain 512 or source/drain 582) of the LDMOS transistor. As a result, the parasitic NPN bipolar transistor becomes self-sustaining, and the increasing number of carriers causes avalanche multiplication in the high electric field region. This, in turn, causes single event burnout causing the LDMOS device without the SEB mitigation structures to fail.

With continued reference to FIG. 5, to mitigate the SEB, during the formation of bidirectional NLDMOS device 500, some or all of SEB mitigation structures 542, 546, 548, 552, 566, and 568 may be formed. SEB mitigation structures 542, 546, 548, 552, 566, and 568 may be formed by implanting P-type dopants into the P-type substrate 502. Using masks, P-type dopants are implanted in a manner that SEB mitigation structure 542 is formed with an edge 543 that is spaced from an edge 511 of N-type region 510 by a distance of S1 and with another edge 545 that is spaced from an edge 581 of N-type region 580 by the distance of S1. The distance S1 may have a value of zero, such that the edge 543 of SEB mitigation structure 542 is adjacent to edge 511 of N-type region 510. As used herein, the use of the term “adjacent” includes the arrangement where SEB mitigation structure 542 may be formed in a region below N-type region 510 and N-type region 580. Similarly, the edge 545 of SEB mitigation structure 542 can be adjacent to edge 581 of N-type region 580 even though SEB mitigation structure 542 may be formed in a region below N-type region 510 and N-type region 580. SEB mitigation structure 542 decreases the resistance to the current that is flowing as a result of the particle strike between substrate 502 and either of P+body contact 514 or P+body contact 584. In other words, in the absence of SEB mitigation structure 542, there will be a higher resistance path for any current flowing from substrate 502 to the P+ body contact.

In addition, SEB mitigation structure 546 is formed with an edge 547 that is spaced from an edge 513 of N-type region 510 by a distance of S2. Moreover, SEB mitigation structure 548 is formed with an edge 549 that is spaced from an edge 583 of N-type region 580 by a distance of S2. The distance S2 may have a value of zero, such that the edge 547 of SEB mitigation structure 546 is adjacent to edge 513 of N-type region 510. As used herein, the use of the term “adjacent” includes the arrangement where SEB mitigation structure 546 may be formed in a region below N-type region 510. Similarly, the edge 549 of SEB mitigation structure 548 can be adjacent to edge 583 of N-type region 580 even though SEB mitigation structure 548 may be formed in a region below N-type region 580. In this manner, each of SEB mitigation structures 546 and 548 is spaced away from a respective N-type region (e.g., N-type region 510 or N-type region 580) by the same distance S2. Each of SEB mitigation structures 546 and 548 also lower the resistance to the current flowing through bidirectional NLDMOS device 500.

Still referring to FIG. 5, to further mitigate SEB, during the formation of bidirectional NLDMOS device 500, SEB mitigation structure 552 may be formed. SEB mitigation structure 552 may be formed by implanting P-type dopants into the P-type substrate 502. Using masks, P-type dopants are implanted in a manner that SEB mitigation structure 552 is formed with an edge 553 that is spaced from edge 511 of N-type region 510 by a distance of S3 and spaced from edge 581 of N-type region 580 by a distance of S3. The distance S3 is usually greater than the distance S1 described earlier with respect to SEB mitigation structure 542. In other words, SEB mitigation structure 552 is spaced further away from N-type region 510 relative to SEB mitigation structure 542. Similarly, SEB mitigation structure 552 is spaced further away from N-type region 580 relative to SEB mitigation structure 542. SEB mitigation structure 552 also helps decrease the resistance to the current that is flowing as a result of the energetic strike between substrate 502 and the P+body contact 514 or the P+body contact 584. In other words, in the absence of SEB mitigation structure 552, there will be a higher resistance path for any current flowing from substrate 502 to the respective P+ body contact.

In addition, SEB mitigation structure 566 can be formed with an edge 567 that is spaced from an edge 513 of N-type region 510 by a distance of S4. Moreover, SEB mitigation structure 568 can be formed with an edge 569 that is spaced from an edge 583 of N-type region 580 by a distance of S4. In this manner, each of SEB mitigation structures 566 and 568 is spaced away from a respective N-type region (e.g., N-type region 510 or N-type region 580) by the same distance S4. Each of SEB mitigation structures 566 and 568 also lower the resistance to the current flowing through bidirectional NLDMOS device 500.

Still referring to FIG. 5, if it is known that during operation in its planned applications either source 512 or source 582 is intended to be at the same potential as the substrate 502, to further mitigate SEB, during the formation of bidirectional NLDMOS device 500, various methods, like silicidation, can be employed to minimize the resistance between the adjacent body contact and that source region. This opposes the forward biasing of the junction between the source intended to be at substrate potential (either source 512 or source 582) and substrate 502, and thereby mitigates the initiation of the SEB event.

SEB mitigation structures 542, 546, 548, 552, 566, and 568 can be formed regardless of whether bidirectional NLDMOS device 500 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 5 shows a specific configuration of SEB mitigation structures 542, 546, 548, 552, 566, and 568 in terms of their location and shape, the SEB mitigation structures may be formed in additional, or alternative, locations and may have different shapes than shown in FIG. 5. As an example, SEB mitigation structures 542, 546, and 548 could be formed as a single blanket layer formed at a depth beneath N-type regions like 510. The use of the blanket layer as one, or a part, of the SEB mitigation structures may allow one to remove additional processing steps associated with the formation of separate SEB mitigation structures 542, 546 and 548.

In another example, the integrated circuit having NLDMOS devices may also include complimentary metal-oxide semiconductor (CMOS) devices, which may be formed in different areas of the chip. In such an example, SEB mitigation structures 552, 566, and 568 along with one or more of SEB mitigation structures 542, 546, and 548 may be the layers that are formed in the areas corresponding to the CMOS devices. Alternatively, SEB mitigation structures 552, 566, and 568 along with a single blanket layer replacing SEB mitigation structures 542, 546, and 548 may be the layers that are formed in the areas corresponding to the CMOS devices. One function of such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

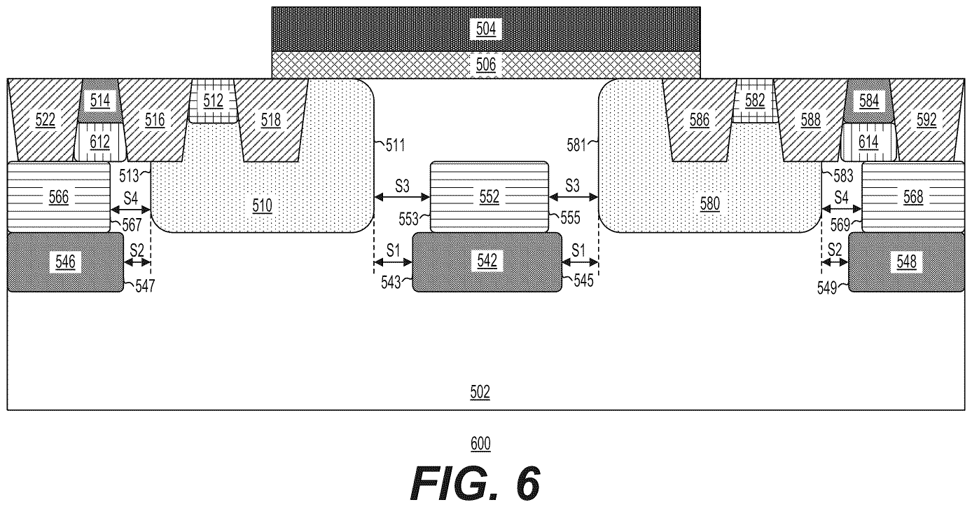

FIG. 6 shows a cross-section view of several single event burnout (SEB) mitigation structures formed in a bidirectional LDMOS device 600 in accordance with another example. To illustrate the structure and the functionality of the SEB mitigation structures, certain portions of bidirectional NLDMOS device 600 are emphasized. A complete bidirectional NLDMOS device may include contacts and other structures for operation that are not shown in FIG. 6. The use of the SEB mitigation structures formed in bidirectional NLDMOS device 600, however, is not limited to a particular implementation of the bidirectional NLDMOS. In addition, the SEB mitigation structures described herein can be used with other high-voltage device designs, including Insulating Gate Bipolar Transistors (IGBTs), vertical double-diffused metal-oxide semiconductor (VDMOS) devices or trench metal-oxide semiconductor (TMOS) devices.

The same or similar regions or structures that are shown in FIG. 6 are referred to using the same reference numbers as used in FIG. 5. As an example, bidirectional NLDMOS device 600 includes the SEB mitigation structures 542, 546, 548, 552, 566, and 568 described earlier with respect to FIG. 5. In addition, bidirectional NLDMOS device 600 includes SEB mitigation structures 612 and 614. Using masks, P-type dopants are implanted to form SEB mitigation structure 612 and SEB mitigation structure 614. SEB mitigation structure 612 also helps decrease the resistance to the current that is flowing as a result of the particle strike between substrate 502 and the P+body contact 514 by acting as a low resistance link between SEB mitigation structure 566 and P+body contact 514. Similarly, SEB mitigation structure 614 also helps decrease the resistance to the current that is flowing as a result of an energetic strike between substrate 502 and the P+ body contact 584 by acting as a low resistance link between SEB mitigation structure 568 and P+ body contact 584.

Depending on the process platform, SEB mitigation structures 612 and 614 may be made with one implant or a chain of multiple implants of different energies. Two such examples are a P-type SEB mitigation structure formed by a single boron implant with dose between 1×10¹² and 1×10¹⁵ and energy between 25 keV and 600 keV or the SEB mitigation structure formed by a chain of two boron implants, one with dose between 1×10¹² and 1×10¹⁵ and energy between 25 keV and 150 keV and a second with dose between 1×10¹² and 1×10¹⁵ and energy between 150 keV and 600 keV.

With continued reference to FIG. 6, SEB mitigation structures 542, 546, 548, 552, 566, 568, 612, and 614 can be formed regardless of whether bidirectional NLDMOS device 600 is fabricated in bulk silicon, silicon films, such as silicon-on-insulator (SOI) substrates, or another semiconductor. In the case of an SOI substrate, a P-type semiconductor layer may be formed in the SOI substrate. Although FIG. 6 shows a specific configuration of SEB mitigation structures 542, 546, 548, 552, 566, 568, 612, and 614 in terms of their location and shape, the SEB mitigation structures may be formed in additional, or alternative, locations and may have different shapes than shown in FIG. 6. As an example, SEB mitigation structures 542, 546, and 548 could be formed as a single blanket layer formed at a depth beneath N-type regions like 510. The use of the blanket layer as one, or a part, of the SEB mitigation structures may allow one to remove additional processing steps associated with the formation of separate SEB mitigation structures 542, 546 and 548.

In another example, the integrated circuit having NLDMOS devices may also include complimentary metal-oxide semiconductor (CMOS) devices, which may be formed in different areas of the chip. In such an example, SEB mitigation structures 612, 614, 552, 566, and 568 along with one or more of SEB mitigation structures 542, 546, and 548 may be the layers that are formed in the areas corresponding to the CMOS devices. Alternatively, SEB mitigation structures 612, 614, 552, 566, and 568 along with a single blanket layer replacing SEB mitigation structures 542, 546, and 548 may correspond to the layers formed in the areas corresponding to the CMOS devices. One function of the such layers is to reduce the onset of latch-up in the areas corresponding to the CMOS devices. Using the same layers in both the areas in which the CMOS devices are formed and the areas in which the high-voltage devices are formed, helps one to control both the cost and the complexity of the fabrication processes.

Still referring to FIG. 6, if it is known that during operation in its planned applications either source 512 or source 582 is intended to be at the same potential as the substrate 502, to further mitigate SEB, during the formation of bidirectional NLDMOS device 600, various methods, like silicidation, can be employed to minimize the resistance between the adjacent body contact and that source region. This opposes the forward biasing of the junction between the source intended to be at substrate potential (either source 512 or source 582) and substrate 502, and thereby mitigates the initiation of the SEB event.

Although not shown in each of FIGS. 1-6, substrate regions 110, 210 and 502 can be electrically isolated from other substrate regions in the integrated circuit through means such as junction isolation or dielectric isolation.

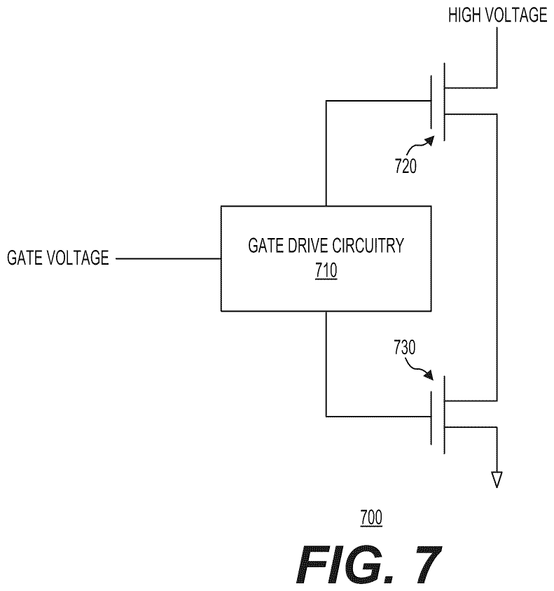

FIG. 7 is a diagram of a circuit 700 that has an a transistor 730 external to and in series with an LDMOS transistor 720 for an NLDMOS device (or another high-voltage device) in accordance with one example. As part of circuit 700, the common gate voltage is coupled via gate drive circuitry 710 to the respective gates of both LDMOS transistor 720 and external transistor 730. The gates of transistors 720 and 730 could also be biased separately. Since both LDMOS transistor 720 and external transistor 730 would be exposed to radiation simultaneously, to maximize the SEB performance of the pair, the external transistor 730 (arranged in series with LDMOS transistor 720) will also need to be SEL-resistant and SEB-resistant in order to protect the LDMOS transistor 720 from a single event burnout (SEB) event. Transistor 730 can be made SEL-resistant and SEB-resistant through various means, including the addition of appropriately engineered implants to the transistor.

In this example, to minimize (or reduce) the resistance penalty of external transistor 730, the transistor type with the highest conductivity should be used. In most technology nodes, this will be one of the available low-voltage (LV) transistor types which likely cannot sustain the same gate-source voltage and/or drain-source voltage as the high-voltage transistor. Therefore, there is a trade-off between minimizing the conductivity loss (e.g., associated with a thicker gate oxide) for a low-voltage transistor and the ease of design associated with gate drive circuitry 710 for use with a low-voltage transistor having the same gate oxide thickness as the high-voltage transistor. In general, low-voltage transistors need to be protected from the high drain voltages that the high-voltage transistors experience; and, so, such low-voltage transistors should be used on the low side of the combination, as shown in FIG. 7. In general, similar to transistor 730, other low-voltage transistors in the IC need to be made SEB-resistant in order for the entire IC to meet its SEB specifications. Different means, including the addition of appropriately engineered implants to the transistor, can be used.

In conclusion, the present disclosure relates to a high-breakdown voltage semiconductor device comprising a substrate of a first conductivity type. The high-breakdown voltage semiconductor device may further comprise a well of a second conductivity type, opposite of the first conductivity type, formed in the substrate. The high-breakdown voltage semiconductor device may further comprise a source and a drain, where the high-breakdown voltage semiconductor device is configured to withstand a high-breakdown voltage between the drain and the source, and a body contact.

The high-breakdown voltage semiconductor device may further comprise a first single event burnout (SEB) structure formed in a first region of the substrate, where a first edge of the first SEB structure: (1) is adjacent to a first edge of the well of the second conductivity type, or (2) is arranged at a first distance from the first edge of the well of the second conductivity type. The high-breakdown voltage semiconductor device may further comprise a second SEB structure formed in a second region of the substrate, above the first SEB structure, where a second edge of the second SEB structure is arranged at a second distance, equal to or greater than the first distance, from the first edge of the well of the second conductivity type, and where a combination of the first SEB structure and the second SEB structure is configured to offer a low resistance path to any current flow between the substrate and the body contact caused by an ionizing strike associated with the high-breakdown voltage semiconductor device.

The first conductivity type may comprise P-type, and the first SEB structure may be formed by implanting the P-type dopants in the first region of the substrate. The second SEB structure may be formed by implanting the P-type dopants in the second region of the substrate.

The high-breakdown voltage semiconductor device may further comprise a third SEB structure formed in a third region of the substrate, different from the first region of the substrate and the second region of the substrate. A third edge of the third SEB structure: (1) may be adjacent to a second edge of the well of the second conductivity type, opposite to the first edge of the well of the second conductivity type, or (2) may be arranged at a third distance, equal to the first distance, from the second edge of the well of the second conductivity type. The first conductivity type may comprise P-type, and the third SEB structure may be formed by implanting the P-type dopants in the third region of the substrate.

The high-breakdown voltage semiconductor device may comprise a unidirectional non-isolated laterally-diffused metal oxide semiconductor (NLDMOS) device formed in a first area of a chip and complementary metal-oxide semiconductor (CMOS) devices formed in a second area, different from the first area, of the chip. Some or all of the single event burnout (SEB) structures formed in the first area may be formed using similar types of materials as used to form radiation protection structures in the second area.

In another aspect, the present disclosure relates to a high-breakdown voltage semiconductor device comprising a substrate of a first conductivity type. The high-breakdown voltage semiconductor device may further comprise a well of a second conductivity type, opposite of the first conductivity type, formed in the substrate. The high-breakdown voltage semiconductor device may further comprise a source and a drain, where the high-breakdown voltage semiconductor device is configured to withstand a high-breakdown voltage between the drain and the source, and a body contact.

The high-breakdown voltage semiconductor device may further comprise a first single event burnout (SEB) structure formed in a first region of the substrate, where a first edge of the first SEB structure: (1) is adjacent to a first edge of the well of the second conductivity type, or (2) is arranged at a first distance from the first edge of the well of the second conductivity type. The high-breakdown voltage semiconductor device may further comprise a second SEB structure formed in a second region of the substrate, above the first SEB structure, where a second edge of the second SEB structure is arranged at a second distance, equal to or greater than the first distance, from the first edge of the well of the second conductivity type.

The high-breakdown voltage semiconductor device may further comprise a third SEB structure formed in a third region of the substrate, above the second SEB structure, where a third edge of the third SEB structure is arranged at a third distance, equal to or greater than the second distance, from the first edge of the well of the second conductivity type. The combination of the first SEB structure, the second SEB structure, and the third SEB structure is configured to offer a low resistance path to any current flow between the substrate and the body contact caused by an ionizing strike associated with the high-breakdown voltage semiconductor device.

The first conductivity type may comprise P-type, and the first SEB structure may be formed by implanting the P-type dopants in the first region of the substrate. The second SEB structure may be formed by implanting the P-type dopants in the second region of the substrate. The third SEB structure may be formed by implanting the P-type dopants in the third region of the substrate.

The high-breakdown voltage semiconductor device may further comprise a fourth SEB structure formed in a fourth region of the substrate, different from the first region of the substrate, the second region of the substrate, and the third region of the substrate. A fourth edge of the fourth SEB structure may be adjacent to a second edge of the well of the second conductivity type, opposite to the first edge of the well of the second conductivity type, or may be away from the second edge of the well of the second conductivity type by a fourth distance, equal to the first distance. The fourth SEB structure may be formed by implanting the P-type dopants in the fourth region of the substrate.

The high-breakdown voltage semiconductor device may comprise a unidirectional non-isolated laterally-diffused metal oxide semiconductor (NLDMOS) device formed in a first area of a chip and complementary metal-oxide semiconductor (CMOS) devices formed in a second area, different from the first area, of the chip. Some or all of the single event burnout (SEB) structures formed in the first area may be formed using similar types of materials as used to form radiation protection structures in the second area.

In yet another aspect, the present disclosure relates to a high-breakdown voltage semiconductor device comprising a substrate and a first well formed in the substrate. The high-breakdown voltage semiconductor device may further comprise a first region formed in the first well, where the first region is configurable as a first source or a first drain. The high-breakdown voltage semiconductor device may further comprise a second well formed in the substrate. The high-breakdown voltage semiconductor device may further comprise a second region formed in the second well, where the second region is configurable as a second source or a second drain, allowing the high-breakdown voltage semiconductor device to operate as a bidirectional device.

The high-breakdown voltage semiconductor device may further comprise a first single event burnout (SEB) structure formed in a first region of the substrate, where a first edge of the first SEB structure: (1) is adjacent to a first edge of the first well, or (2) is arranged at a first distance from the first edge of the first well, and where a second edge of the first SEB structure: (1) is adjacent to a second edge of the second well, or (2) is arranged at second distance, equal to the first distance, from the second edge of the second well. The high-breakdown voltage semiconductor device may further comprise a second SEB structure formed in a second region of the substrate, above the first SEB structure, where a third edge of the second SEB structure is arranged at a third distance, equal to or greater than the first distance, from the first edge of the first well, and where a fourth edge of the second SEB structure is arranged at a fourth distance, equal to the third distance, from the second edge of the second well. The combination of the first SEB structure and the second SEB structure is configured to offer a low resistance path to any current flow between the substrate and the first body contact or between the substrate and the second body contact caused by an ionizing strike associated with the high-breakdown voltage semiconductor device.

The substrate may be of a first conductivity type, and each of the first well and the second well may be of a second conductivity type, opposite of the first conductivity type. The first conductivity type may comprise P-type, and the first SEB structure may be formed by implanting the P-type dopants in the first region of the substrate. The second SEB structure may be formed by implanting the P-type dopants in in the second region of the substrate.

The high-breakdown voltage semiconductor device may further comprise: (1) a third SEB structure formed in a third region of the substrate, different from the first region of the substrate and the second region of the substrate, where an edge of the third SEB structure: (a) is adjacent to a third edge of the first well, opposite to the first edge of the first well, or (b) is arranged at a fifth distance from the third edge of the first well, and (2) a fourth SEB structure formed in a fourth region of the substrate, different from the first region of the substrate, the second region of the substrate, and the third region of the substrate, where an edge of the fourth SEB structure: (a) is adjacent to a fourth edge of the second well, opposite to the second edge of the second well, or (b) is arranged at a sixth distance from the fourth edge of the second well. The third SEB structure may be formed by implanting the P-type dopants in the third region of the substrate. The fourth SEB structure may be formed by implanting the P-type dopants in the fourth region of the substrate.

The high-breakdown voltage semiconductor device may further comprise: (1) a fifth SEB structure formed in a fifth region of the substrate, above the third SEB structure, where an edge of the fifth SEB structure: (a) is adjacent to the third edge of the first well, opposite to the first edge of the first well, or (b) is arranged at a seventh distance from the third edge of the first well, and (2) a sixth SEB structure formed in a sixth region of the substrate, above the third SEB structure, where an edge of the sixth SEB structure: (a) is adjacent to the fourth edge of the second well, opposite to the second edge of the second well, or (b) is arranged at an eighth distance from the fourth edge of the second well. The fifth SEB structure may be formed by implanting the P-type dopants in the fifth region of the substrate. The sixth SEB structure is formed by implanting the P-type dopants in the sixth region of the substrate.

high-breakdown voltage semiconductor device may further comprise: (1) a seventh SEB structure formed in a seventh region of the substrate, above the fifth SEB structure, where the seventh SEB structure is configured to offer a low resistance path to any current flow between the substrate and the first body contact caused by single event burnout associated with the high-breakdown voltage semiconductor device, and (2) an eighth SEB structure formed in an eighth region of the substrate, above the sixth SEB structure where the eighth SEB structure is configured to offer a low resistance path to any current flow between the substrate and the second body contact caused by single event burnout associated with the high-breakdown voltage semiconductor device.

It is to be understood that the processes and components depicted herein are merely exemplary. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A high-breakdown voltage semiconductor device comprising:
a substrate of a first conductivity type;
a well of a second conductivity type, opposite of the first conductivity type, formed in the substrate;
a source;
a drain, wherein the high-breakdown voltage semiconductor device is configured to withstand a high-breakdown voltage between the drain and the source;
a body contact;
a first single event burnout (SEB) structure formed in a first region of the substrate, wherein a first edge of the first SEB structure: (1) is adjacent to a first edge of the well of the second conductivity type, or (2) is arranged at a first distance from the first edge of the well of the second conductivity type; and
a second SEB structure formed in a second region of the substrate, above the first SEB structure, wherein a second edge of the second SEB structure is arranged at a second distance, equal to or greater than the first distance, from the first edge of the well of the second conductivity type, and wherein a combination of the first SEB structure and the second SEB structure is configured to offer a low resistance path to any current flow between the substrate and the body contact caused by an ionizing strike associated with the high-breakdown voltage semiconductor device.

2. The high-breakdown voltage semiconductor device of claim 1, wherein the first conductivity type comprises P-type, and wherein the first SEB structure is formed by implanting the P-type dopants in the first region of the substrate.

3. The high-breakdown voltage semiconductor device of claim 2, wherein the second SEB structure is formed by implanting the P-type dopants in the second region of the substrate.

4. The high-breakdown voltage semiconductor device of claim 1, further comprising a third SEB structure formed in a third region of the substrate, different from the first region of the substrate and the second region of the substrate, wherein a third edge of the third SEB structure: (1) is adjacent to a second edge of the well of the second conductivity type, opposite to the first edge of the well of the second conductivity type, or (2) is arranged at a third distance, equal to the first distance, from the second edge of the well of the second conductivity type.

5. The high-breakdown voltage semiconductor device of claim 1, wherein the first conductivity type comprises P-type, and wherein the third SEB structure is formed by implanting the P-type dopants in the third region of the substrate.

6. The high-breakdown voltage semiconductor device of claim 1, wherein the high-breakdown voltage semiconductor device comprises a unidirectional non-isolated laterally-diffused metal oxide semiconductor (NLDMOS) device formed in a first area of a chip and complementary metal-oxide semiconductor (CMOS) devices formed in a second area, different from the first area, of the chip, and wherein some or all of the single event burnout (SEB) structures formed in the first area are formed using similar types of materials as used to form radiation protection structures in the second area.

7. A high-breakdown voltage semiconductor device comprising:
a substrate of a first conductivity type;
a well of a second conductivity type, opposite of the first conductivity type, formed in the substrate;
a source;
a drain, wherein the high-breakdown voltage semiconductor device is configured to withstand a high-breakdown voltage between the drain and the source;
a body contact;
a first single event burnout (SEB) structure formed in a first region of the substrate, wherein a first edge of the first SEB structure: (1) is adjacent to a first edge of the well of the second conductivity type, or (2) is arranged at a first distance from the first edge of the well of the second conductivity type;
a second SEB structure formed in a second region of the substrate, above the first SEB structure, wherein a second edge of the second SEB structure is arranged at a second distance, equal to or greater than the first distance, from the first edge of the well of the second conductivity type;
a third SEB structure formed in a third region of the substrate, above the second SEB structure, wherein a third edge of the third SEB structure is arranged at a third distance, equal to or greater than the second distance, from the first edge of the well of the second conductivity type, and wherein a combination of the first SEB structure, the second SEB structure, and the third SEB structure is configured to offer a low resistance path to any current flow between the substrate and the body contact caused by an ionizing strike associated with the high-breakdown voltage semiconductor device.

8. The high-breakdown voltage semiconductor device of claim 7, wherein the first conductivity type comprises P-type, and wherein the first SEB structure is formed by implanting the P-type dopants in the first region of the substrate.

9. The high-breakdown voltage semiconductor device of claim 8, wherein the second SEB structure is formed by implanting the P-type dopants in the second region of the substrate.

10. The high-breakdown voltage semiconductor device of claim 9, wherein the third SEB structure is formed by implanting the P-type dopants in the third region of the substrate.

11. The high-breakdown voltage semiconductor device of claim 10, further comprising a fourth SEB structure formed in a fourth region of the substrate, different from the first region of the substrate, the second region of the substrate, and the third region of the substrate, wherein a fourth edge of the fourth SEB structure is adjacent to a second edge of the well of the second conductivity type, opposite to the first edge of the well of the second conductivity type, or is away from the second edge of the well of the second conductivity type by a fourth distance, equal to the first distance.

12. The high-breakdown voltage semiconductor device of claim 11, wherein the fourth SEB structure is formed by implanting the P-type dopants in the fourth region of the substrate.

13. The high-breakdown voltage semiconductor device of claim 7, wherein the high-breakdown voltage semiconductor device comprises a unidirectional non-isolated laterally-diffused metal oxide semiconductor (NLDMOS) device formed in a first area of a chip and complementary metal-oxide semiconductor (CMOS) devices formed in a second area, different from the first area, of the chip, and wherein some or all of the single event burnout (SEB) structures formed in the first area are formed using similar types of materials as used to form radiation protection structures in the second area.

14. A high-breakdown voltage semiconductor device comprising:
a substrate;
a first well formed in the substrate;
a first region formed in the first well, wherein the first region is configurable as a first source or a first drain;
a second well formed in the substrate;
a second region formed in the second well, wherein the second region is configurable as a second source or a second drain, allowing the high-breakdown voltage semiconductor device to operate as a bidirectional device;
a first single event burnout (SEB) structure formed in a first region of the substrate, wherein a first edge of the first SEB structure: (1) is adjacent to a first edge of the first well, or (2) is arranged at a first distance from the first edge of the first well, and wherein a second edge of the first SEB structure: (1) is adjacent to a second edge of the second well, or (2) is arranged at a second distance, equal to the first distance, from the second edge of the second well; and
a second SEB structure formed in a second region of the substrate, above the first SEB structure, wherein a third edge of the second SEB structure is arranged at a third distance, equal to or greater than the first distance, from the first edge of the first well, and wherein a fourth edge of the second SEB structure is arranged at a fourth distance, equal to the third distance, from the second edge of the second well, and wherein a combination of the first SEB structure and the second SEB structure is configured to offer a low resistance path to any current flow between the substrate and the first body contact or to any current flow between the substrate and the second body contact caused by an ionizing strike associated with the high-breakdown voltage semiconductor device.

15. The high-breakdown voltage semiconductor device of claim 14, wherein the substrate is of a first conductivity type, wherein each of the first well and the second well is of a second conductivity type, opposite of the first conductivity type, wherein the first conductivity type comprises P-type, and wherein the first SEB structure is formed by implanting the P-type dopants in the first region of the substrate, and wherein the second SEB structure is formed by implanting the P-type dopants in in the second region of the substrate.

16. The high-breakdown voltage semiconductor device of claim 15, further comprising:
(1) a third SEB structure formed in a third region of the substrate, different from the first region of the substrate and the second region of the substrate, wherein an edge of the third SEB structure: (a) is adjacent to a third edge of the first well, opposite to the first edge of the first well, or (b) is arranged at a fifth distance from the third edge of the first well; and
(2) a fourth SEB structure formed in a fourth region of the substrate, different from the first region of the substrate, the second region of the substrate, and the third region of the substrate, wherein an edge of the fourth SEB structure: (a) is adjacent to a fourth edge of the second well, opposite to the second edge of the second well, or (b) is arranged at a sixth distance from the fourth edge of the second well.

17. The high-breakdown voltage semiconductor device of claim 16, wherein the third SEB structure is formed by implanting the P-type dopants in the third region of the substrate, and wherein the fourth SEB structure is formed by implanting the P-type dopants in the fourth region of the substrate.

18. The high-breakdown voltage semiconductor device of claim 17, further comprising:
(1) a fifth SEB structure formed in a fifth region of the substrate, above the third SEB structure, wherein an edge of the fifth SEB structure: (a) is adjacent to the third edge of the first well, opposite to the first edge of the first well, or (b) is arranged at a seventh distance from the third edge of the first well; and
(2) a sixth SEB structure formed in a sixth region of the substrate, above the third SEB structure, wherein an edge of the sixth SEB structure: (a) is adjacent to the fourth edge of the second well, opposite to the second edge of the second well, or (b) is arranged at an eighth distance from the fourth edge of the second well.

19. The high-breakdown voltage semiconductor device of claim 16, wherein the fifth SEB structure is formed by implanting the P-type dopants in the fifth region of the substrate, and wherein the sixth SEB structure is formed by implanting the P-type dopants in the sixth region of the substrate.

20. The high-breakdown voltage semiconductor device of claim 19, further comprising:
(1) a seventh SEB structure formed in a seventh region of the substrate, above the fifth SEB structure, wherein the seventh SEB structure is configured to offer a low resistance path to any current flow between the substrate and the first body contact caused by single event burnout associated with the high-breakdown voltage semiconductor device; and
(2) an eighth SEB structure formed in an eighth region of the substrate, above the sixth SEB structure, wherein the eighth SEB structure is configured to offer a low resistance path to any current flow between the substrate and the second body contact caused by single event burnout associated with the high-breakdown voltage semiconductor device.
